(19) United States
(12) Patent Application Publication
(10) Pub. No.: US 2010/0142258 A1
(43) Pub. Date: Jun. 10, 2010

(54) TEN-TRANSISTOR STATIC RANDOM ACCESS MEMORY ARCHITECTURE

(76) Inventors: Tsung-Heng TSAI, Min-Hsiung (TW); Kian-Ann GAN, Min-Hsiung (TW)

Correspondence Address: SINORICA, LLC, 2275 Research Blvd., Suite 500, ROCKVILLE, MD, 20850, US

(21) Appl. No.: 12/436,914

(22) Filed: May 7, 2009

(30) Foreign Application Priority Data
Dec. 5, 2008 (TW) 97147569

(51) Int. Cl. G11C 11/00; G11C 7/00

(52) U.S. Cl. 365/154; 365/189.011

(57) ABSTRACT

The present invention discloses a 10T SRAM architecture, wherein two symmetric data access paths are added to a 6T SRAM architecture. Each data access path has two transistors, whereby the read signals are no more driven by the memory unit, wherefore the dimensions of the transistors inside the 10T SRAM cell are no more limited by the required driving capability. Thus, the 10T SRAM architecture can use the minimum-size transistors to achieve a higher operation speed and meet the requirement of the high-speed digital circuit. Further, the 10T SRAM cell of the present invention can achieve an SNM-free feature.

### BACKGROUND OF THE INVENTION

1. Field of the Invention

The present invention relates to a SRAM cell, particularly to a ten-transistor SRAM cell having two additional symmetric data-access paths.

2. Description of the Related Art

SRAM (Static Random Access Memory) is a semiconductor memory and belongs to the RAM family. In SRAM, the stored data will be persistently maintained as long as electricity is held thereinside. Contrarily, the data needs periodically updating in DRAM (Dynamic Random Access Memory). Because of the symmetric circuit structure of SRAM, the data in SRAM can be accessed faster than that in DRAM under same operation frequency. Compare to DRAM where high-address and low-address bits are being read alternately, all bits are read in once within most SRAM which provide higher reading efficiency of SRAM than that of DRAM.

As SRAM far outperforms DRAM in convenience and functions, SRAM is the first choice among RAM for most electronic industries. The six-transistor (6T) architecture is most frequently used in SRAM. However, the conventional 6T SRAM confronts more and more design difficulties during the evolution of fabrication processes. In the advanced processes, the system voltage is decreased persistently, but the leakage current of the gate becomes more serious. Further, the mismatch caused by process variation is likely to result in instability and access errors in SRAM.

Refer to FIG. 1A for a conventional 6T SRAM. In this 6T SRAM architecture, the inverter formed by MR1 and MR2 and the inverter formed by MR3 and MR4 function as the memory unit; MR5 and MR6 provide the access paths. To achieve a larger static noise margin (SNM), the dimensions of the memory cell should be enlarged. However, a larger memory cell decelerates the output speed. Basically, SRAM consumes power only in state transition. However, decreasing the power consumed in the standby state has become an important subject in SRAM design since the number of the memory cells per unit area rapidly increases with the advance of the fabrication process. Refer to FIG. 1B for the current leakage paths of SRAM in the standby state. When the data Q stored in the memory cell is “1”, the junction current iⱼ flows from Q to the bulk material, and the current passing through the oxide layer is designated by i_{tunneling}.

To overcome the abovementioned problems, the present invention proposes a ten-transistor (10T) SRAM architecture, wherein two symmetric data access paths are added to conventional 6T SRAM architecture, whereby the read signal is no more driven by the memory unit. The 10T SRAM of the present invention has multiple threshold voltages, an SNM-free feature, low standby power consumption, and a sure-write scheme. Further, the dimensions of the transistors inside the 10T SRAM cell are no more limited by the required driving capability. Therefore, the 10T SRAM architecture can use the minimum-size transistors to achieve a higher operation speed and meets the requirement of the high-speed digital circuit.

### SUMMARY OF THE INVENTION

The primary objective of the present invention is to provide a SRAM architecture, particularly a ten-transistor SRAM architecture, which has two additional symmetric data access paths.

The 10T SRAM cell of the present invention comprises a memory unit, two data access units, and two noise-immunity units. The memory unit includes two inverters, and each inverter includes a load transistor and a pass transistor. The switching activities of the inverters enable the memory unit to store data. Each of the two data access units contains an access transistor. Each access transistor controls one inverter, whereby the data is accessed via the word line. The two noise-immunity units are respectively arranged beside the two data access units symmetrically and form two symmetric noise-immunity circuit structures at two sides of the memory unit, whereby the memory unit has better noise-immunity capability. Further, the two noise-immunity units connect with the bit lines and word lines and thus provide additional data access paths for the memory unit, whereby the read signals of the bit lines are no more driven by the memory unit. Therefore, the dimensions of the transistors inside the memory unit are no more limited by the required driving capability, and the 10T SRAM architecture can use the minimum-size transistors to achieve a higher operation speed and meet the requirement of the high-speed digital circuit. Further, the 10T SRAM cell of the present invention can achieve an SNM-free feature.

Below, the embodiments of the present invention will be described in detail in cooperation with the attached drawings to make easily understood the objectives, technical contents, characteristics and accomplishments of the present invention.

### BRIEF DESCRIPTION OF THE DRAWINGS

FIG. 1A is a diagram schematically showing a 6T SRAM architecture;

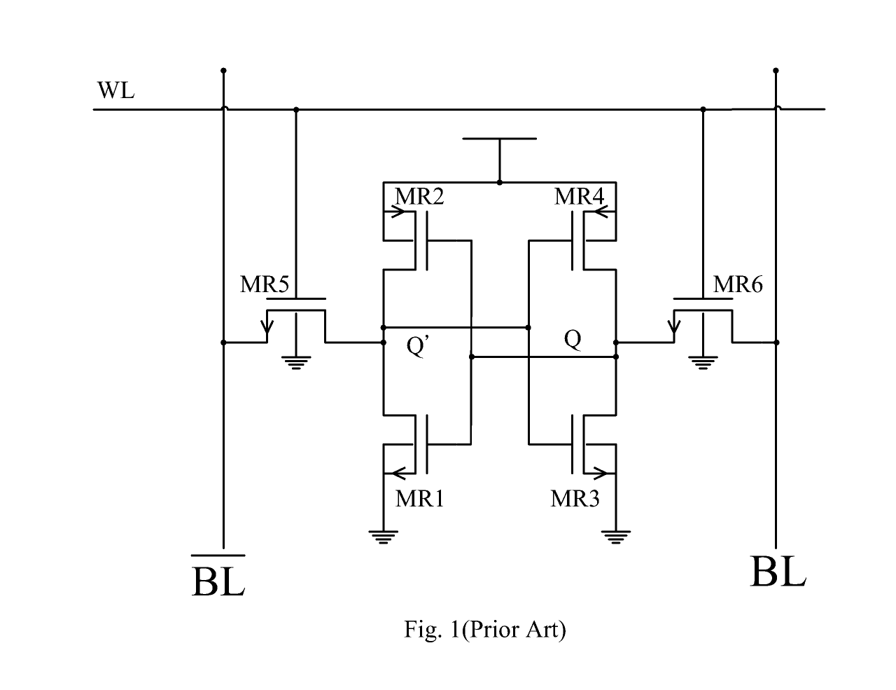

FIG. 1B is a diagram schematically showing the current leakage paths of a 6T SRAM in the standby state; and

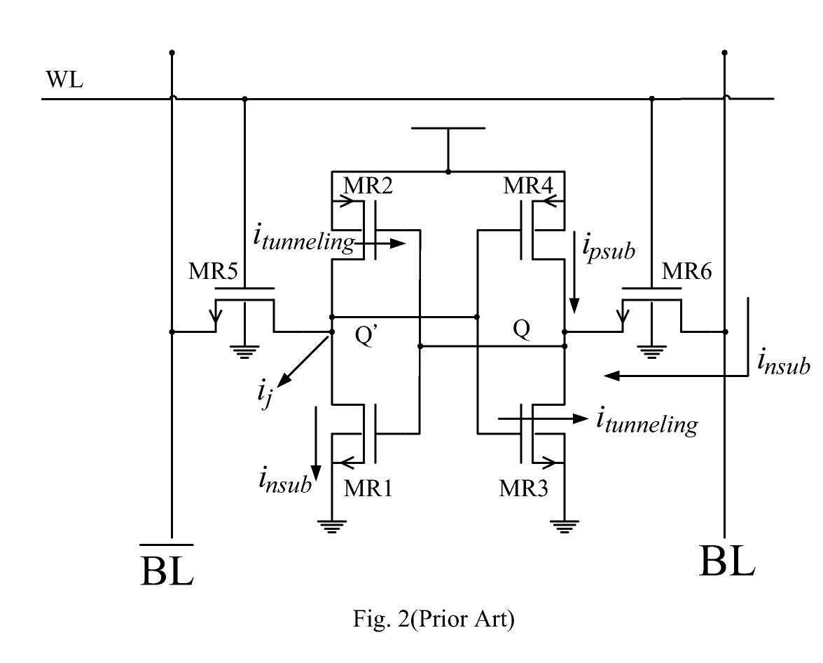

FIG. 2 is a diagram schematically showing the architecture of a 10T SRAM cell according to the present invention.

### DETAILED DESCRIPTION OF THE INVENTION

The present invention discloses a SRAM architecture, particularly a ten-transistor SRAM architecture, which has two additional symmetric data access paths that can also function as the noise-immunity circuit.

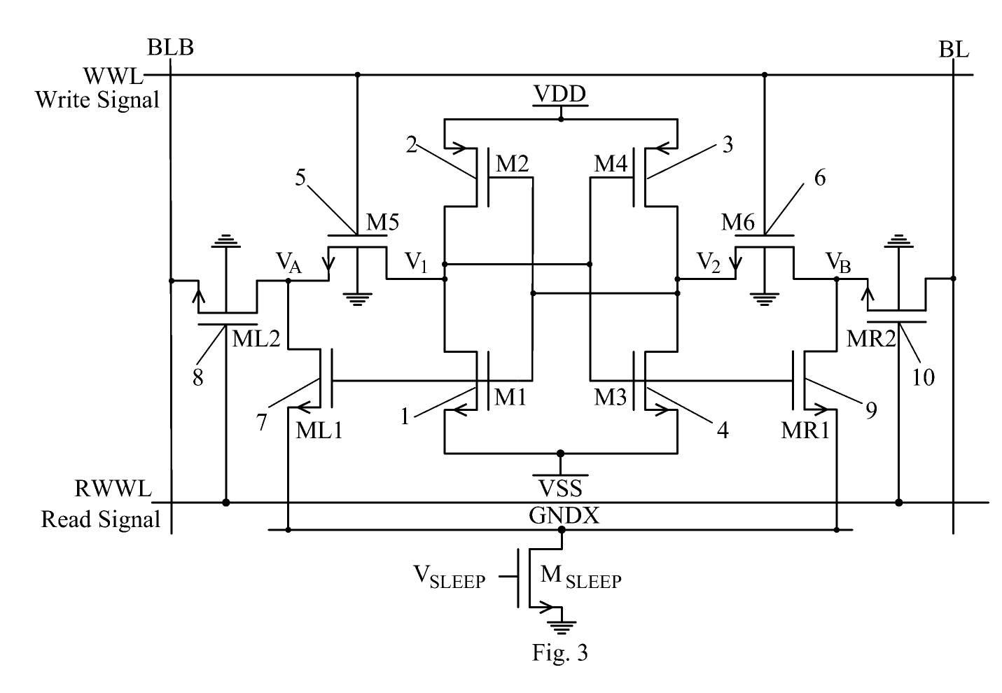

Refer to FIG. 2 for the architecture of a 10T SRAM cell according to the present invention. The 10T SRAM cell of the present invention comprises a memory unit, two data access units, and two noise-immunity units. The memory unit includes two inverters, and each inverter includes a load transistor 1 (or 3) and a pass transistor 2 (or 4). The switching activities of the inverters enable the memory unit to store data. Each of the two data access units contains an access transistor 5 (or 6). Each access transistor 5 (or 6) controls one inverter, whereby the data is accessed via the word line. The two noise-immunity units respectively contain a pair of transistors 7 and 8 and a pair of transistors 9 and 10. The two noise-immunity units are respectively arranged beside the two data access units symmetrically, whereby the memory unit has better noise-immunity capability. Further, the two noise-immunity units connect with the bit lines and word lines and thus provide additional data access paths for the memory unit, whereby the read signals of the bit lines are no more driven by the memory unit. The abovementioned architecture provides higher stability and longer persistence for the single pair of bit lines (BL and BLB). The 10T SRAM cell of the present invention is characterized in that new data access paths are respectively added to the original data access paths of the bit lines of the 6T SRAM architecture, and that the new data access paths are symmetrically arranged with respect to the original data access paths. The two new data access paths respectively contain a pair of transistors 7 (ML1) and 8 (ML2) and a pair of transistors 9 (MR1) and 10 (MR2) and form two symmetric noise-immunity circuit structures at two sides of the 6T SRAM architecture.

In the conventional 6T SRAM architecture, the high SNM (Static Noise Margin) state reflects the fact that the size of transistors must be carefully designed to maintain the stability and function of data in the 6T SRAM. In the present invention, the read signals of the bit lines are no more driven by the memory unit because of the additional data access paths. Therefore, the dimensions of the transistors inside the memory unit are no more limited by the required driving capability, and the 10T SRAM architecture can use the minimum-size transistors to achieve a higher operation speed and meet the requirement of the high-speed digital circuit. Further, the 10T SRAM cell of the present invention can achieve a SNM-free feature.

The additional data access paths not only can maintain the SRAM of the present invention at the highest stability but also makes the current conduction capability of the load transistors 1(M1) and 3(M3) as small as that of the access transistors 5(M5) and 6(M6). Thus, the current conduction capability of the load transistors 1(M1) and 3(M3) is not necessarily at the level of the current conduction capability of the load transistors in the conventional 6T SRAM. Therefore, the dimensions of the transistors are no more limited in the present invention. In the conventional 6T SRAM, the access transistors have to use a current higher than the current used by the pass transistors 2 (M2) and 4 (M4) in the writing state. Contrarily, the present invention is exempt from the limit because the load transistors 1(M1) and 3(M3) are maintained in the minimum size. The additional data access paths have another advantage that the reading and writing activities of the same memory cell can be completed in the same cycle, which can greatly promote the efficiency of the memory cell.

In the present invention, the access activities of the 10T SRAM cell are controlled via RWL (Read Word Line), and RWL can also connect the bit lines to the ground (GNDX) to maintain the highest static noise margin without interfering with the reading activities. In the writing operation, WWL (Write Word Line) and RWL will turn on to provide a writing path from the bit lines to the memory unit. The two additional pairs of transistors 7 (ML1) and 8 (ML2) and transistors 9 (MR1) and 10 (MR2) may be realized with low-threshold voltage (Vₜₕ) NMOS (N-channel Metal Oxide Semiconductor) to enhance the performance thereof. As NMOS is SNM-free, the threshold voltage of NMOS in the SRAM cell can be decreased to the lowest level the threshold voltage of the CMOS (Complementary Metal Oxide Semiconductor) logic transistor can reach. The present invention may replace the Footer of the load transistor with a higher-threshold voltage Footer to decrease at least 90% leakage current. Because of minimizing the cell size and decreasing the bit-line leakage current, the leakage current in the 10T SRAM cell of the present invention is less than that in the 6T SRAM cell by about 22.9%.

The embodiments described above are only to exemplify the present invention but not to limit the scope of the present invention. Therefore, any equivalent modification or variation according to the shapes, structures, characteristics and spirit disclosed in the present invention is to be also included within the scope of the present invention.

What is claimed is:

1. A ten-transistor static random access memory architecture comprising
a memory unit including two inverters and storing data via switching activities of said inverters;
two data access units respectively controlling said two inverters to enable data to be accessed via word lines; and
two noise-immunity units respectively arranged beside said two data access units symmetrically, connected to bit lines and said word lines, and providing additional data access paths for said memory unit to make read signals of said bit lines no more driven by said memory unit.

2. The ten-transistor static random access memory architecture according to claim 1, wherein said inverters includes a load transistor and a pass transistor.

3. The ten-transistor static random access memory architecture according to claim 2, wherein current conduction capability of said load transistor is same small size as that of an access transistor.

4. The ten-transistor static random access memory architecture according to claim 2, wherein current used by said load transistor does not need to be higher than current used by said pass transistor.

5. The ten-transistor static random access memory architecture according to claim 1, wherein said data access unit includes an access transistor.

6. The ten-transistor static random access memory architecture according to claim 1, wherein each said noise-immunity unit includes two transistors.

7. The ten-transistor static random access memory architecture according to claim 6, wherein said two transistors are low-threshold voltage N-channel metal-oxide-semiconductor transistors.

8. The ten-transistor static random access memory architecture according to claim 1, wherein said noise-immunity units maintain said memory unit at highest stability.

9. The ten-transistor static random access memory architecture according to claim 1, wherein reading and writing activities of a memory cell is completed in an identical cycle.

10. The ten-transistor static random access memory architecture according to claim 1, wherein dimensions of transistors in said memory architecture are not limited by driving capability of said memory unit.

11. The ten-transistor static random access memory architecture according to claim 1, wherein said bit lines are grounded via a read word line to maintain highest static noise margin without interfering with reading activities.
